(19) United States
(12) Patent Application Publication
(10) Pub. No.: US 2026/0020159 A1
(43) Pub. Date: Jan. 15, 2026

(54) ELECTRONIC DEVICE AND MANUFACTURING METHOD THEREOF

(71) Applicant: Samsung Electronics Co., Ltd., Suwon-si (KR)

(72) Inventor: Inhee Yoo, Suwon-si (KR)

(21) Appl. No.: 19/009,010

(22) Filed: Jan. 3, 2025

(30) Foreign Application Priority Data
Jul. 12, 2024 (KR) 10-2024-0092585

(51) Int. Cl. H05K 1/18; H01G 4/30

(52) U.S. Cl. CPC H05K 1/181; H01G 4/30; H05K 2201/10015

(57) ABSTRACT

Provided is an electronic device including a printed circuit board (PCB), a multilayer ceramic capacitor mounted on the PCB, wherein the multilayer ceramic capacitor includes a ceramic body and a plurality of internal electrodes inside the ceramic body, and an insulating layer between the PCB and the multilayer ceramic capacitor, wherein the insulating layer is in contact with the PCB and the multilayer ceramic capacitor.

### CROSS-REFERENCE TO RELATED APPLICATION

This application is based on and claims priority under 35 U.S.C. § 119 to Korean Patent Application No. 10-2024-0092585, filed Jul. 12, 2024, in the Korean Intellectual Property Office, the disclosure of which is incorporated by reference herein in its entirety.

### BACKGROUND

The inventive concept relates to electronic devices and manufacturing methods thereof, and more particularly, to electronic devices including multilayer ceramic capacitors, and manufacturing methods thereof.

A multilayer ceramic capacitor includes a plurality of dielectric layers, a plurality of internal electrodes arranged opposite to each other and separated by one of the plurality of dielectric layers, and a plurality of external electrodes electrically connected to the plurality of internal electrodes. Such multilayer ceramic capacitors are widely used in electronic devices such as computers, mobile phones, and control modules due to their advantageous small size, high capacitance, and easy mounting. In recent years, as electronic devices have become smaller and more multifunctional, chip devices are also becoming smaller and more multifunctional, and thus, products with a small size and a large capacitance are required for electronic devices.

### SUMMARY

The inventive concept provides an electronic device with increased reliability and a manufacturing method thereof.

In addition, the task to be solved by the technical idea of the inventive concept is not limited to the above-mentioned task, and other tasks not mentioned above may be clearly understood by those of ordinary skill in the art from the following description.

According to an aspect of the inventive concept, there is provided an electronic device including a printed circuit board (PCB), a multilayer ceramic capacitor mounted on the PCB, wherein the multilayer ceramic capacitor comprises a ceramic body and a plurality of internal electrodes inside the ceramic body, and an insulating layer between the PCB and the multilayer ceramic capacitor, wherein the insulating layer is in contact with the PCB and the multilayer ceramic capacitor.

According to an aspect of the inventive concept, there is provided an electronic device including a printed circuit board (PCB), wherein the PCB comprises a base layer and a first and a second electrode pads formed on the base layer, a multilayer ceramic capacitor mounted on the PCB, and an insulating layer between the PCB and the multilayer ceramic capacitor, wherein the insulating layer is in contact with the PCB and the multilayer ceramic capacitor, and wherein the multilayer ceramic capacitor comprising a ceramic body including a plurality of internal electrodes alternately arranged with a plurality of dielectric layers, and a plurality of external electrodes on the ceramic body and electrically connected to the plurality of internal electrodes.

According to another aspect of the inventive concept, there is provided an electronic device including a printed circuit board (PCB), wherein the PCB comprises a base layer and a first and a second electrode pads formed on the base layer, a multilayer ceramic capacitor mounted on the PCB, and an insulating layer between the PCB and the multilayer ceramic capacitor, wherein the insulating layer is in contact with the PCB and the multilayer ceramic capacitor, and wherein the multilayer ceramic capacitor comprises a ceramic body comprising a plurality of first and second internal electrodes alternately arranged with a plurality of dielectric layers, and a first external electrode and a second external electrode, on opposing faces of the ceramic body, wherein the first external electrode is electrically connected to the plurality of first internal electrodes, and the second external electrode is electrically connected to the plurality of second internal electrodes.

According to another aspect of the inventive concept, there is provided a method of manufacturing an electronic device, the method including preparing a printed circuit board (PCB), mounting an insulating layer on the PCB, and mounting a multilayer ceramic capacitor on the PCB and the insulating layer.

### BRIEF DESCRIPTION OF THE DRAWINGS

Embodiments will be more clearly understood from the following detailed description taken in conjunction with the accompanying drawings in which:

FIG. 1 is a perspective view illustrating a multilayer ceramic capacitor according to an example embodiment;

FIG. 2 is a cross-sectional view taken along line II-II′ of FIG. 1;

FIG. 3 is a perspective view illustrating an electronic device on which a multilayer ceramic capacitor is mounted, according to an example embodiment;

FIG. 4 is a cross-sectional view illustrating an electronic device on which a multilayer ceramic capacitor is mounted, according to an example embodiment;

FIG. 5 is a perspective view illustrating an electronic device on which a multilayer ceramic capacitor is mounted, according to an example embodiment;

FIG. 6 is a cross-sectional view illustrating an electronic device on which a multilayer ceramic capacitor is mounted, according to an example embodiment;

FIG. 7 is a cross-sectional view illustrating an electronic device on which a multilayer ceramic capacitor is mounted, according to an example embodiment;

FIGS. 8, 9 and 10 are cross-sectional views illustrating a method of manufacturing an electronic device on which a multilayer ceramic capacitor is mounted, according to an example embodiment; and

FIGS. 11, 12, 13, and 14 are cross-sectional views illustrating a method of manufacturing an electronic device on which a multilayer ceramic capacitor is mounted, according to an example embodiment.

### DETAILED DESCRIPTION OF THE EMBODIMENTS

Hereinafter, embodiments of the inventive concept will be described in detail with reference to the accompanying drawings. The same reference numerals are used for the same devices in the drawings, and redundant descriptions thereof are omitted. In the following drawings, the thickness or size of each layer is exaggerated for convenience and clarity of explanation, and accordingly, may be slightly different from the actual shape and ratio.

The terms “first,” “second,” etc., may be used herein merely to distinguish one component, layer, direction, etc. from another. The terms “comprises,” “comprising,” “includes” and/or “including,” when used herein, specify the presence of stated elements, but do not preclude the presence of additional elements. The term “and/or” includes any and all combinations of one or more of the associated listed items. The term “on” as used herein, may not refer to complete surrounding or covering of the described elements or layers but may, for example, refer to partially surrounding or covering the described elements or layers.

Spatially relative terms such as ‘on,’ ‘above,’ ‘upper,’ ‘lower,’ ‘side,’ and the like may be used herein to describe elements or features with reference to the drawings. However, it will be understood that such spatially relative terms are intended to encompass different orientations of the device in use or operation in addition to the orientation depicted in the figures. For example, if the device in the figures is turned over, elements described as on other elements or features would then be oriented below or lower than the other elements or features.

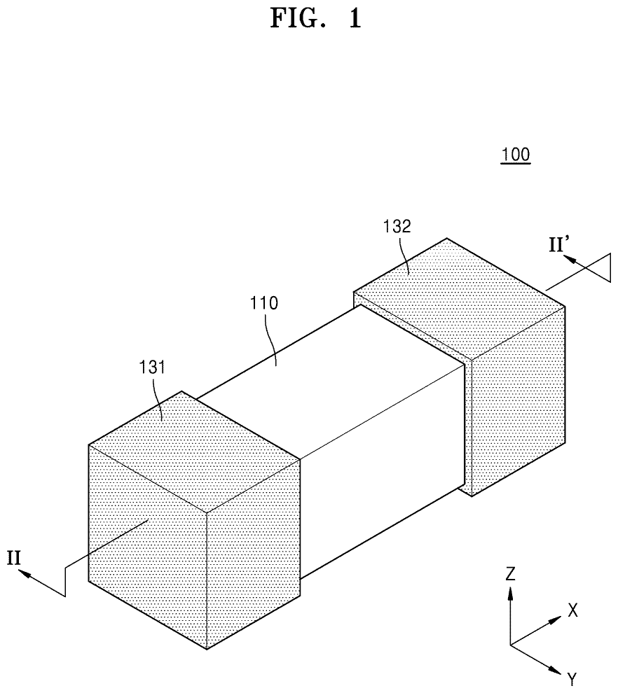

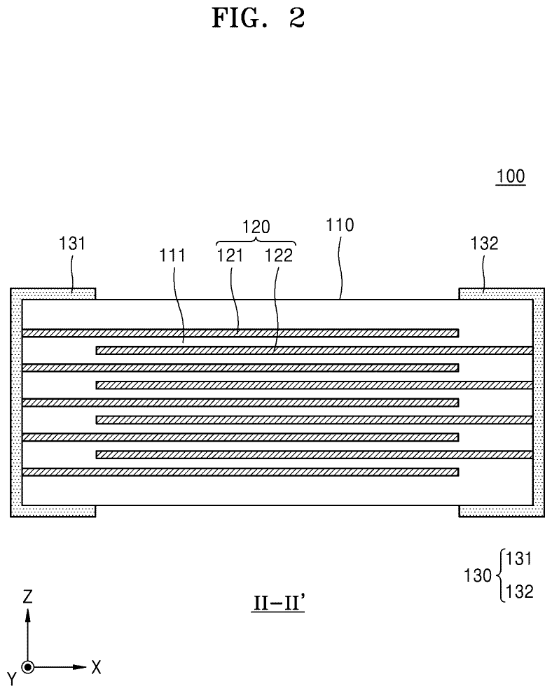

FIG. 1 is a perspective view illustrating a multilayer ceramic capacitor according to an example embodiment. FIG. 2 is a cross-sectional view taken along line II-Il′ of FIG. 1.

Referring to FIGS. 1 and 2, a multilayer ceramic capacitor 100 may include a ceramic body 110 and a plurality of internal electrodes 120 formed inside the ceramic body 110.

The ceramic body 110 may include an active layer as a portion contributing to the capacitance formation of a capacitor, and upper and lower cover layers formed on the upper and lower portions of the active layer as upper and lower margin regions, respectively. The active layer may include a plurality of dielectric layers 111 and a plurality of internal electrodes 120.

In some embodiments, the ceramic body 110 is not particularly limited in its shape but may have a hexahedral shape. Due to the thickness difference according to the presence of the internal electrode pattern and the abrasion of the edge region of the ceramic body 110, the ceramic body 110 may not have a complete hexahedral shape but may have a shape close to a hexahedral shape.

When the direction of the hexahedron is defined to clearly describe the technical idea of the inventive concept, the X, Y, and Z directions shown on the drawings represent a longitudinal direction, a width direction, and a thickness direction, respectively. Here, the thickness direction may be used as the same concept as the stacking direction in which the plurality of dielectric layers 111 are stacked. Components or layers described with reference to being “stacked”, may be arranged in vertical or axial alignment, where each layer or component is directly or indirectly aligned with the previous one in a vertical direction or along a particular axis.

Each one of the plurality of internal electrodes 120 includes a first internal electrode of the plurality of first internal electrodes 121 and a second internal electrode of the plurality of second internal electrodes 122, and the plurality of first and second internal electrodes 121 and 122 may be arranged to extend forwardly from opposite sides of the ceramic body 110 with one of the plurality of dielectric layers 111 therebetween. The first and second internal electrodes 121 and 122 are a pair of electrodes having different polarities, and may have a predetermined thickness, in the Z direction between the plurality of dielectric layers 111.

In addition, the plurality of first and second internal electrodes 121 and 122 may be exposed through both sides of the ceramic body 110 along the stacking direction (i.e. Z direction) of the dielectric layer 111, and may be electrically insulated from each other by one of the plurality of dielectric layers 111 therebetween.

That is, the plurality of first and second internal electrodes 121 and 122 may be electrically connected to one of the plurality of external electrodes 130 through portions exposed through both cross-sections of the ceramic body 110. More specifically, the plurality of external electrodes 130 may include a first external electrode 131 and a second external electrode 132, the plurality of first internal electrodes 121 may be electrically connected to the first external electrode 131, and the plurality of second internal electrodes 122 may be electrically connected to the second external electrode 132.

Therefore, when voltage is applied to the first and second external electrodes 131 and 132, charge may be accumulated between the plurality of first and second internal electrodes 121 and 122, and in this case, the capacitance of the multilayer ceramic capacitor 100 may be proportional to an area of a region where the plurality of first and second internal electrodes 121 and 122 overlap each other. Elements or components described with reference to having “overlap” with each other in at least one particular direction may be at least partially obstructed by one another when viewed along a line extending in the particular direction or in a plane perpendicular to the particular direction. The “overlap” may be direct with components directly on other components or there may be intervening layers or components between the layers.

The thickness of each one of the plurality of first and second internal electrodes 121 and 122 may be determined according to a use. In this case, the thickness of the dielectric layer 111 may be changed according to the capacitance needs of the multilayer ceramic capacitor 100. In addition, the plurality of first and second internal electrodes 121 and 122 may include a conductive metal, and the conductive metal may be, but is not limited to, silver (Ag), copper (Cu), nickel (Ni), tin (Sn), and gold (Au), or alloys thereof. In an example embodiment, the plurality of first and second internal electrodes 121 and 122 may include at least one of palladium (Pd), platinum (Pt), tungsten (W), titanium (Ti), and alloys thereof.

In addition, ceramic powder having a high dielectric constant (e.g. barium titanate-based material, lead composite perovskite-based material, strontium titanate-based material, or the like) may be used as the dielectric layer 111. The barium titanate-based material may include a BaTiO₃-based ceramic powder, (e.g. (Ba₁₋ₓCaₓ)TiO₃, Ba(Ti_{1-y}Ca_{y})O₃, (Ba₁₋ₓCaₓ)(Ti_{1-y}Zr_{y})O₃, Ba(Ti_{1-y}Zr_{y})O₃, or the like) in which calcium (Ca), zirconium (Zr), and the like are partially dissolved in BaTiO₃. As the material forming the dielectric layer 111, various ceramic additives, organic solvents, plasticizers, binders, and/or dispersants may be added to powders such as barium titanate (BaTiO₃) according to the purpose of the inventive concept.

The uppermost region and the lowermost region of the dielectric layer 111 may have the same material and configuration as those of the plurality of dielectric layers 111 in other regions, without including the plurality of internal electrodes 120. Each of the uppermost region and the lowermost region may be formed by stacking a single dielectric layer or two or more dielectric layers in a vertical direction (i.e. Z direction) and may serve to prevent damage to the plurality of first and second internal electrodes 121 and 122 by physical or chemical stress.

Specifically, regarding the plurality of external electrodes 130, the first and second external electrodes 131 and 132, respectively are electrically connected to the plurality of first and second internal electrodes 121 and 122 to ensure electrical conduction between the outside and the inside of the ceramic body 110.

In an example embodiment, the first and second external electrodes 131 and 132 may include a conductive metal, and the conductive metal may be nickel (Ni), copper (Cu), palladium (Pd), gold (Au), or an alloy thereof, but is not limited thereto. In an example embodiment, the first and second external electrodes 131 and 132 may include at least one of platinum (Pt), tungsten (W), titanium (Ti), and alloys thereof.

In this specification, a direction in which the ceramic body 110 is present is defined as an inner side and a direction in which the ceramic body 110 is not present is defined as an outer side with respect to the plurality of external electrodes 130.

In general, the multilayer ceramic capacitor 100 includes a plurality of stacked dielectric layers 111, a plurality of internal electrodes 120 facing each other with the dielectric layer 111 therebetween, and a plurality of external electrodes 130 electrically connected to the plurality of internal electrodes 120. These multilayer ceramic capacitors 100 are widely used as devices for electronic devices such as computers, mobile phones, and control modules due to their advantages of a small size, high capacitance, and easy mounting.

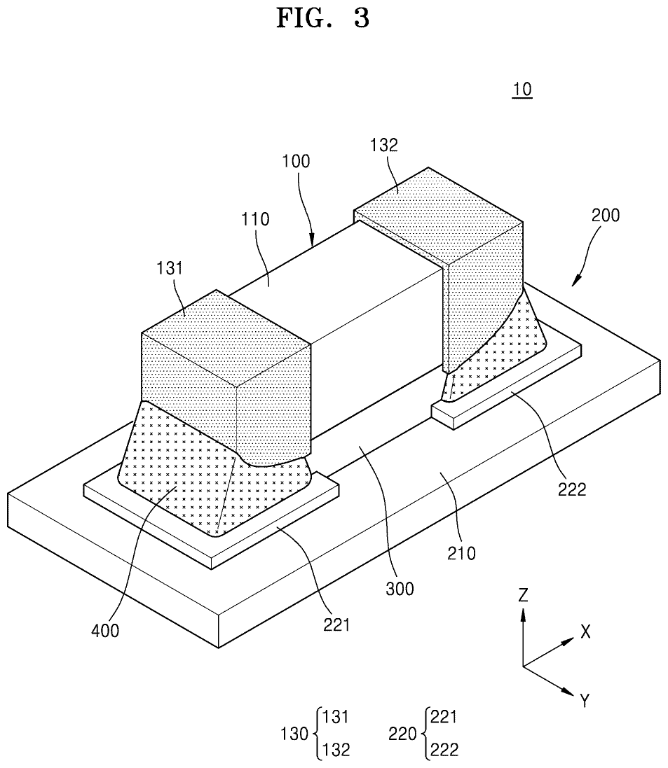

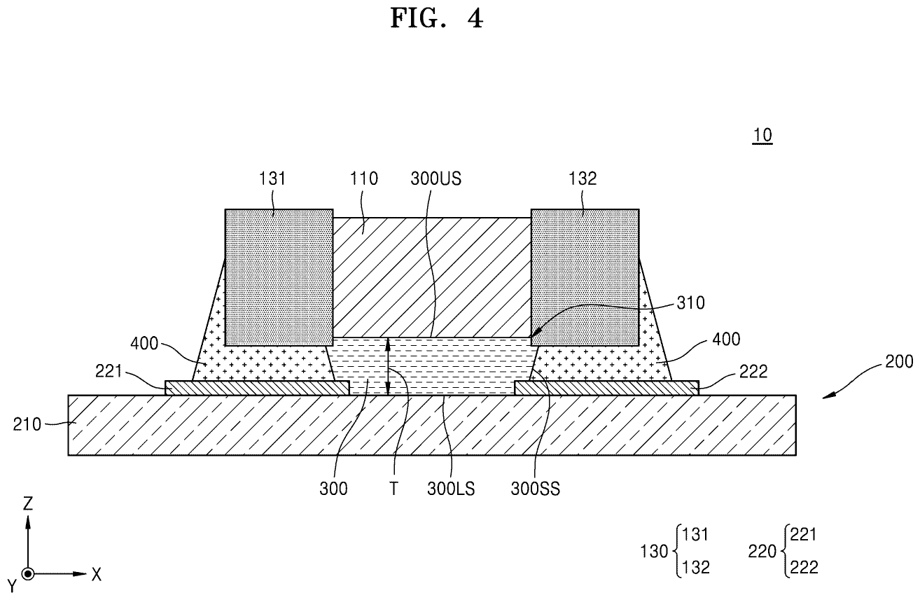

FIG. 3 is a perspective view illustrating an electronic device on which a multilayer ceramic capacitor is mounted according to an example embodiment. FIG. 4 is a cross-sectional view illustrating an electronic device on which a multilayer ceramic capacitor is mounted according to an example embodiment. Description will be made with reference to FIGS. 1 and 2.

Referring to FIGS. 3 and 4, an electronic device 10 may include a multilayer ceramic capacitor 100, a printed circuit board (PCB) 200, and an insulating layer 300. The multilayer ceramic capacitor 100 has been described in detail with reference to FIGS. 1 and 2, and a description thereof is omitted herein.

The PCB 200 may include a base layer 210 and first and second electrode pads 221 and 222 arranged on the base layer 210. The base layer 210 may include a body layer, an upper protective layer, and a lower protective layer. Wiring parts are formed in the base layer 210, and the wiring parts on the base layer 210 may be electrically connected to the multilayer ceramic capacitor 100 through a connection terminal. In addition, a port may be arranged on the base layer 210. The base layer 210 may be mounted on and electrically connected to, a module substrate, a system board, a main board, or the like through the port.

A multi-layered or single-layered wiring part may be formed in the body layer, and the body layer may be electrically connected to the multilayer ceramic capacitor 100 through such a wiring part. The upper protective layer and the lower protective layer function to protect the body layer, and in an example embodiment, may include a solder resist.

In addition, the body layer may be implemented by compressing polymer materials such as thermosetting resins, or epoxy resin or phenol resin such as Flame Retardant 4 (FR-4), Bismaleimide Triazine (BT), and Ajinomoto Build up Film (ABF) to a certain thickness, to be formed in a thin shape, applying copper foil on both sides, and forming a wiring part, which is a transfer path of electrical signals, through patterning.

The PCB 200 may be divided into a single layer PCB (PCB) in which wiring is formed only on one surface and a double layer PCB in which wiring is formed on both surfaces. In addition, the number of layers of copper foil can be formed in three or more layers using an insulator called prepreg, and by forming three or more wiring layers according to the number of layers of copper foil formed, a PCB of multi-layered wiring may be implemented. Furthermore, the PCB 200 may be a rigid PCB or a flexible PCB.

The insulating layer 300 is arranged between the multilayer ceramic capacitor 100 and the PCB 200, and may fill a space defined by the multilayer ceramic capacitor 100 and the PCB 200.

A longitudinal length of a top surface 300US of the insulating layer 300 may be different from a longitudinal length of a bottom surface 300LS of the insulating layer 300. In an embodiment, a longitudinal length of a top surface 300US of the insulating layer 300 may be greater than a longitudinal length of a bottom surface 300LS of the insulating layer 300. The insulating layer 300 may have a tapered shape having a longitudinal length that decreases from an upper side to a lower side and extends. In another embodiment, a longitudinal length of the top surface 300US of the insulating layer 300 may be less than a longitudinal length of the bottom surface 300LS of the insulating layer 300.

In an embodiment, the insulating layer 300 may be in contact with each of the multilayer ceramic capacitor 100 and the PCB 200. The top surface 300US of the insulating layer 300 may be in contact with the multilayer ceramic capacitor 100. In an example embodiment, all of a top surface 300US of the insulating layer 300 may be in contact with the multilayer ceramic capacitor 100. The top surface 300US of the insulating layer 300 may be in contact with the ceramic body 110 and the plurality of external electrodes 130. In addition, the top surface 300US of the insulating layer 300 may have a plurality of stepped and/or inclined portions 310. The side surfaces of the insulating layer 300 may have at least one of a plurality of side surfaces 300 SS with a plurality of stepped and/or inclined portions 310. The term “surface” may be used herein to describe the outermost layer or boundary of an element or feature.

The bottom surface 300LS of the insulating layer 300 may be in contact with the PCB 200. In an example embodiment, all of a bottom surface 300LS of the insulating layer 300 may be in contact with the PCB 200. The bottom surface 300LS of the insulating layer 300 may be in contact with the base layer 210 and the plurality of electrode pads 220. The plurality of side surfaces 300SS of the insulating layer 300 may be in contact with a plurality of adhesive members 400.

The thickness T of the insulating layer 300 in the vertical direction (Z direction) may be 20 micrometers. In an example embodiment, the thickness T of the insulating layer 300 in the vertical direction (Z direction) may be 10-30 micrometers.

In an embodiment, the insulating layer 300 may include a material having a Young's modulus of 500 MPa or less. In an example embodiment, the insulating layer 300 may include a material having a Young's modulus of 10 MPa or less. The Young's modulus may be an index indicating the rigidity of a material. The Young's modulus may be the ratio of stress applied to a material to strain due to the stress. Therefore, the lower the Young's modulus, the greater the shape change due to external stress. In an embodiment, when the insulating layer 300 includes a material having a Young's modulus of 500 MPa or less, stress generated at the interface between the multilayer ceramic capacitor 100 and the insulating layer 300 may be released.

The insulating layer 300 may include a material having a coefficient of moisture expansion of 0.1% per % change in RH or less. In an example embodiment, the units of the coefficient of moisture expansion may be the degree of change in the material's dimensions per unit change in moisture content, length change per unit length per unit change in moisture content, % per % change in relative humidity (RH), mm/m per % change in moisture, or other units thereof. Here, the coefficient of moisture expansion may represent a rate of change in dimension that occurs when a material absorbs or loses moisture. As the coefficient of moisture expansion decreases, stability of the material to moisture and resistance to moisture may increase. In an example embodiment, when the insulating layer 300 includes a material having a coefficient of moisture expansion of 0.1% per % change in RH or less, then stress generated at the interface between the multilayer ceramic capacitor 100 and the insulating layer 300 may be easily released.

In an embodiment, the insulating layer 300 may include a die attach film (DAF). However, the technical idea of the inventive concept is not limited thereto, and it goes without saying that the insulating layer 300 may include a material that satisfies the range of the modulus value described above and the range of the coefficient of moisture expansion described above.

The first and second external electrodes 131 and 132 of the multilayer ceramic capacitor 100 may be electrically connected to the first and second electrode pads 221 and 222, respectively. Specifically, the first electrode pad 221 and the first external electrode 131 may be attached by a first adhesive member of the plurality of adhesive members 400, and the second electrode pad 222 and the second external electrode 132 may be attached by a second adhesive member of the plurality of adhesive members 400.

The plurality of adhesive members 400 may include a solder fillet. In an example embodiment, the plurality of adhesive members 400 may include a metal (e.g. lead (Pb), silver (Ag), copper (Cu), bismuth (Bi), indium (In), zinc (Zn), or alloys thereof) but is not limited thereto.

In the method of manufacturing general electronic devices, the modulus of the insulating layer arranged between the multilayer ceramic capacitor and the PCB was relatively high, and the coefficient of moisture expansion was relatively low. Therefore, there was a problem that the stress of the interface could not be released. Furthermore, cracks may occur between the materials constituting the insulating layer, and the cracks may be due to discontinuous surfaces and/or voids.

In contrast, the insulating layer 300 of the electronic device 10 of the inventive concept may include a material having a relatively low Young's modulus value and a relatively low coefficient of moisture expansion. Therefore, the insulating layer (300) of the inventive concept may effectively release the stress generated at the interface between the multilayer ceramic capacitor 100 and the insulating layer 300, and the electronic device 10 of the inventive concept may have high reliability even in high temperature/humidity environments.

Furthermore, the occurrence of cracks in the insulating layer 300 of the electronic device 10 of the inventive concept may be reduced, and the remaining flux inside the insulating layer 300 may also be reduced. Accordingly, the electronic device 10 of the inventive concept may have high reliability.

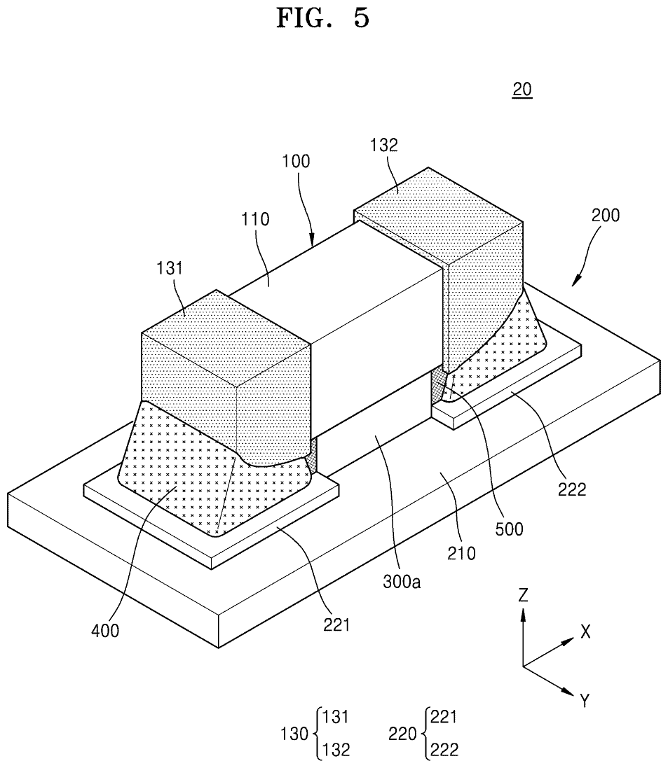

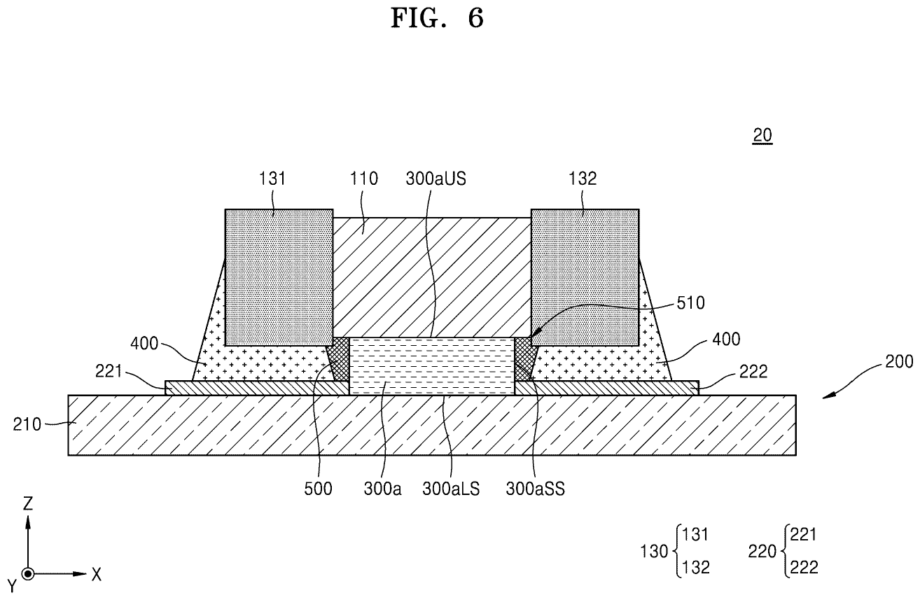

FIG. 5 is a perspective view illustrating an electronic device on which a multilayer ceramic capacitor is mounted according to an example embodiment. FIG. 6 is a cross-sectional view illustrating an electronic device on which a multilayer ceramic capacitor is mounted according to an example embodiment. Description will be made with reference to FIGS. 5 and 6 together with FIGS. 1 to 4.

Referring to FIGS. 5 and 6, an electronic device 20 may include a multilayer ceramic capacitor 100, a PCB 200, an insulating layer 300a, and an auxiliary insulating layer 500. The multilayer ceramic capacitor 100 and the PCB 200 of the electronic device 20 of FIGS. 5 and 6 may be the same as the multilayer ceramic capacitor 100 and the PCB 200 of the electronic device 10 of FIGS. 3 and 4, and here, the insulating layer 300a and the auxiliary insulating layer 500 will be described. For convenience of description, the insulating layer 300a may be referred to as a first insulating layer 300a, and the auxiliary insulating layer 500 may be referred to as a second insulating layer 500.

A cross-section of the first insulating layer 300a may have a rectangular shape. That is, a longitudinal length of a top surface 300aUS of the first insulating layer 300a may be the same as a longitudinal length of a bottom surface 300bLS of the first insulating layer 300a.

When a cross-section of the first insulating layer 300a is rectangular, the first insulating layer 300a may be easily manufactured. However, the technical idea of the inventive concept is not limited thereto, and it goes without saying that the cross-sectional shape of the first insulating layer 300a may vary.

The top surface 300aUS, the bottom surface 300aLS, and/or the plurality of side surfaces 300aSS of the first insulating layer 300a may have flat shapes. The top surface 300aUS of the first insulating layer 300a may be in contact with the multilayer ceramic capacitor 100. The top surface 300aUS of the first insulating layer 300a may be in contact with the ceramic body 110 of the multilayer ceramic capacitor 100. The top surface 300aUS of the first insulating layer 300a may be spaced apart from the plurality of external electrodes 130 in the X direction and/or Y direction.

The bottom surface 300aLS of the first insulating layer 300a may be in contact with the PCB 200. The bottom surface 300aLS of the first insulating layer 300a may be in contact with the base layer 210 of the PCB 200. The plurality of side surfaces 300aSS of the first insulating layer 300a may be in contact with the plurality of electrode pads 220 and the second insulating layer 500. The plurality of side surfaces 300aSS of the first insulating layer 300a may be spaced apart from the plurality of adhesive members 400 in the X direction and/or Y direction.

The second insulating layer 500 may be arranged between the first insulating layer 300a and the plurality of adhesive members 400. The second insulating layer 500 may include a plurality of stepped and/or inclined portions 510 on a top surface thereof. The plurality of side surfaces 300 SS of the second insulating layer 300 may have at least one of a plurality of side surfaces with a plurality of stepped and/or inclined portions 310. The second insulation layer 500 may be in contact with the multilayer ceramic capacitor 100, the plurality of electrode pads 220, the first insulation layer 300a, and the plurality of adhesive members 400. The second insulating layer 500 may fill a space between the side surface 300aSS of the first insulating layer 300a and the multilayer ceramic capacitor 100. The second insulating layer 500 may fill a space between the side surface 300aSS of the first insulating layer 300a and the plurality of adhesive members 400. That is, the second insulating layer 500 may fill a space defined by the multilayer ceramic capacitor 100, the first insulating layer 300a, and the plurality of adhesive members 400. In an example embodiment, the second insulating layer 500 may be a void or free space bounded by the adjacent elements including the plurality of electrode pads 220, the PCB 200, the first insulating layer 300a, and the plurality of adhesive members 400.

The second insulating layer 500 may include a material different from that of the first insulating layer 300a. In an embodiment, the second insulating layer 500 may include a material having a Young's modulus value and/or a coefficient of moisture expansion higher than a Young's modulus and/or a coefficient of moisture expansion of a material constituting the first insulating layer 300a. In an example embodiment, the second insulating layer 500 may include an epoxy molding compound (EMC), but the technical idea of the inventive concept is not limited thereto.

In the electronic device 20, the first insulating layer 300a is mounted between the multilayer ceramic capacitor 100 and the PCB 200, so that the stress generated at the interface may be efficiently released, and the second insulating layer 500 is mounted between the first insulating layer 300a and the plurality of adhesive members 400, so that the space between the multilayer ceramic capacitor 100 and the PCB 200 may be efficiently filled.

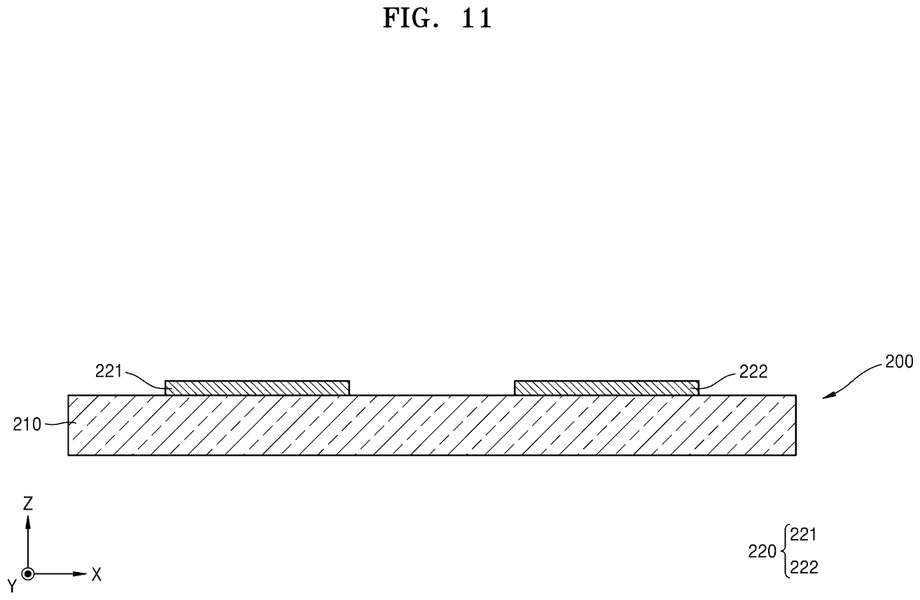

A method of manufacturing the electronic device 20 including the first insulating layer 300a and the second insulating layer 500 is described in detail with reference to FIGS. 11 to 14.

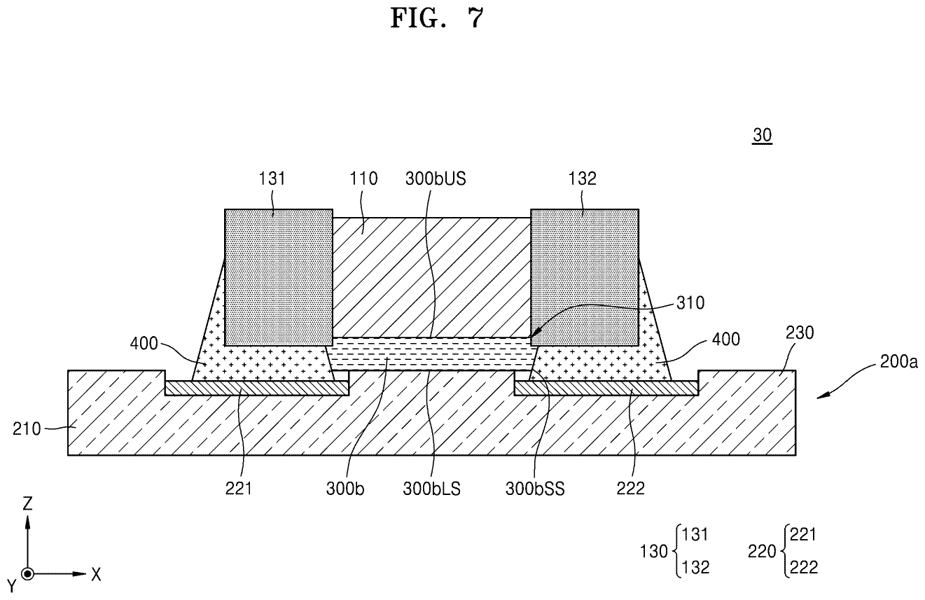

FIG. 7 is a cross-sectional view illustrating an electronic device on which a multilayer ceramic capacitor is mounted according to an example embodiment. A description will be made with reference to FIG. 7 together with FIGS. 3 and 4.

Referring to FIG. 7, an electronic device 30 may include a multilayer ceramic capacitor 100, a PCB 200a, and an insulating layer 300b. The multilayer ceramic capacitor 100 of the electronic device 30 of FIG. 7 may be the same as the multilayer ceramic capacitor 100 of the electronic device 10 of FIGS. 3 and 4, and here, the PCB 200a and the insulating layer 300b will be described.

The PCB 200a may include a base layer 210, an plurality of electrode pads 220, and a solder resist layer 230. The solder resist layer 230 may cover at least a portion of a top surface of the base layer 210 and expose the plurality of electrode pads 220. The top surface of the solder resist layer 230 may be positioned above the top surface of the plurality of electrode pads 220, along a thickness direction.

In an embodiment, the solder resist layer 230 may be formed by applying a solder mask insulating ink onto the top surface of the base layer 210 by a screen printing method or an inkjet printing method and then curing the resultant with heat, ultraviolet (UV) rays, or infrared (IR) rays.

In another embodiment, the solder resist layer 230 may be formed by fully applying a photo-imageable solder resist on a top surface of the base layer 210, by a screen printing method or a spray coating method, or bonding a film-type solder resist material by a laminating method, and then removing unnecessary parts by exposure and development, and curing the resultant by heat, UV, or IR.

The insulating layer 300b may be in contact with the multilayer ceramic capacitor 100, the solder resist layer 230, and the plurality of adhesive members 400. The bottom surface 300bLS of the insulating layer 300b may have a flat shape. The bottom surface 300bLS of the insulating layer 300b may be spaced apart from the plurality of electrode pads 220 in the vertical direction (Z direction). The bottom surface 300bLS of the insulating layer 300b may be in contact with the solder resist layer 230.

The top surface 300bUS of the insulating layer 300b may have a plurality of stepped and/or inclined portions 310. The plurality of side surfaces 300bSS of the insulating layer 300b may have at least one of a plurality of side surfaces with a plurality of stepped and/or inclined portions 310. The top surface 300bUS of the insulating layer 300b may be in contact with the multilayer ceramic capacitor 100. In an example embodiment, all of a top surface 300bUS of the insulating layer 300b may be in contact with the multilayer ceramic capacitor 100. The top surface 300bUS of the insulating layer 300b may be in contact with the ceramic body 110 and the plurality of external electrodes 130. In addition, the plurality of side surfaces 300bSS of the insulating layer 300 may be in contact with the plurality of adhesive members 400.

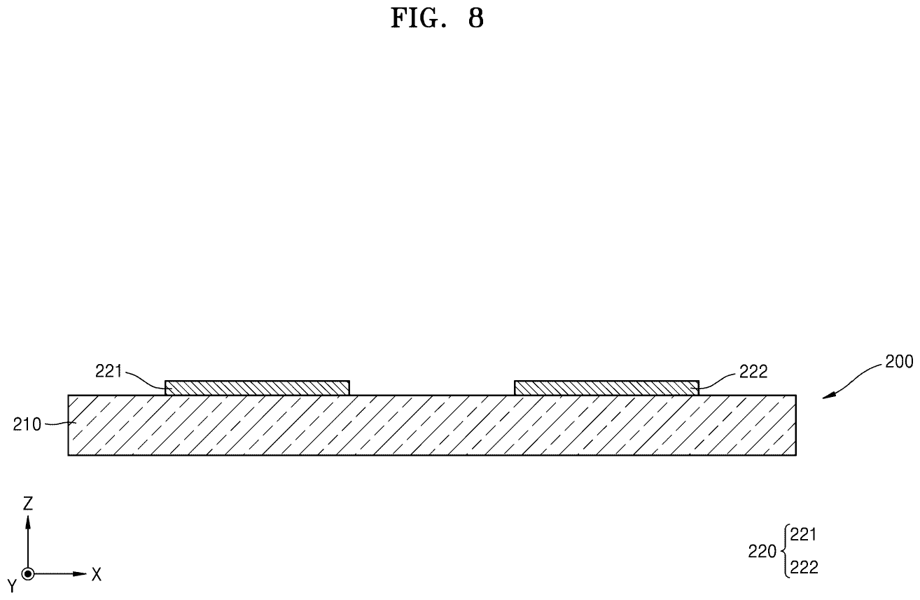

FIGS. 8 to 10 are cross-sectional views illustrating a method of manufacturing an electronic device on which a multilayer ceramic capacitor is mounted, according to an example embodiment. Description will be made with reference to FIGS. 8 to 10 together with FIGS. 1 to 4.

Referring to FIG. 8, first, a PCB 200 including a base layer 210, a first electrode pad 221, and a second electrode pad 222 may be prepared. The base layer 210 may include a body layer, an upper protective layer, and a lower protective layer. Wiring parts are formed in the base layer 210, and the wiring parts on the base layer 210 may be electrically connected to the multilayer ceramic capacitor 100 through a connection terminal. In addition, a port may be arranged on the base layer 210. The base layer 210 may be mounted on, while being electrically connected to, a module substrate, a system board, a main board, or the like through the port.

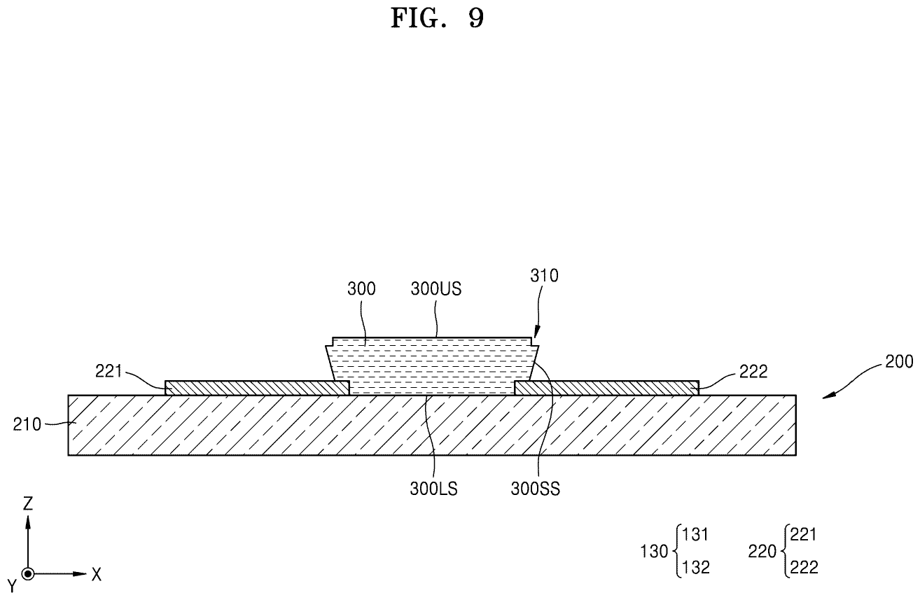

Referring to FIG. 9, an insulating layer 300 may be mounted on the PCB 200. The insulating layer 300 may be mounted on the base layer 210 of the PCB 200. The insulating layer 300 may be mounted between the first and second electrode pads 221 and 222 on which a multilayer ceramic capacitor 100 is to be mounted later. After heating the PCB 200 and the insulating layer 300, the insulating layer 300 may be mounted on the PCB 200.

In an embodiment, the insulating layer 300 may have a shape filling a space generated by the multilayer ceramic capacitor 100 and the PCB 200 later.

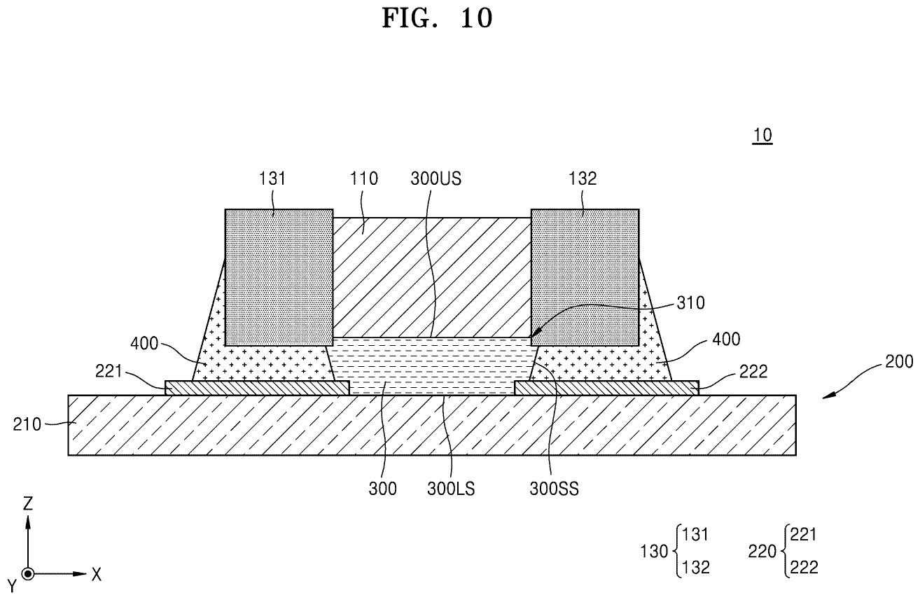

Referring to FIG. 10, the multilayer ceramic capacitor 100 may be mounted on the PCB 200 and the insulating layer 300. After the multilayer ceramic capacitor 100 is mounted on the insulating layer 300, the first electrode pad 221 and the first external electrode 131 may be adhered by a first adhesive member of the plurality of adhesive members 400, and the second electrode pad 222 and the second external electrode 132 may be adhered by a second adhesive member of the plurality of adhesive members 400.

Therefore, after the insulating layer 300 is mounted on the PCB 200, the multilayer ceramic capacitor 100 may be mounted on the PCB 200. The multilayer ceramic capacitor 100 may be mounted on the PCB 200 by the plurality of adhesive members 400. The plurality of adhesive members 400 may be arranged between the plurality of external electrodes 130 and the plurality of electrode pads 220 to electrically and/or physically connect the plurality of external electrodes 130 and the plurality of electrode pads 220 to each other. In addition, the plurality of adhesive members 400 may be in contact with the insulating layer 300. When the plurality of adhesive members 400 are in contact with the insulating layer 300, the insulating layer 300 may be effectively filled inside a space defined by the multilayer ceramic capacitor 100 and the PCB 200.

Therefore, the insulating layer 300 may be in contact with each of the multilayer ceramic capacitor 100 and the PCB 200. In more detail, the insulating layer 300 may be in contact with the ceramic body 110, the plurality of external electrodes 130, the base layer 210, the first electrode pad 221, the second electrode pad 222, and/or the plurality of adhesive members 400.

FIGS. 11 to 14 are cross-sectional views illustrating a method of manufacturing an electronic device on which a multilayer ceramic capacitor is mounted according to an example embodiment. Description will be made with reference to FIGS. 11 to 14 together with FIGS. 1, 2, 5, and 6.

Referring to FIG. 11, first, a PCB 200 including a base layer 210, a first electrode pad 221, and a second electrode pad 222 may be prepared. The preparation of the PCB 200 has been described with reference to FIG. 8, and thus a detailed description thereof is omitted.

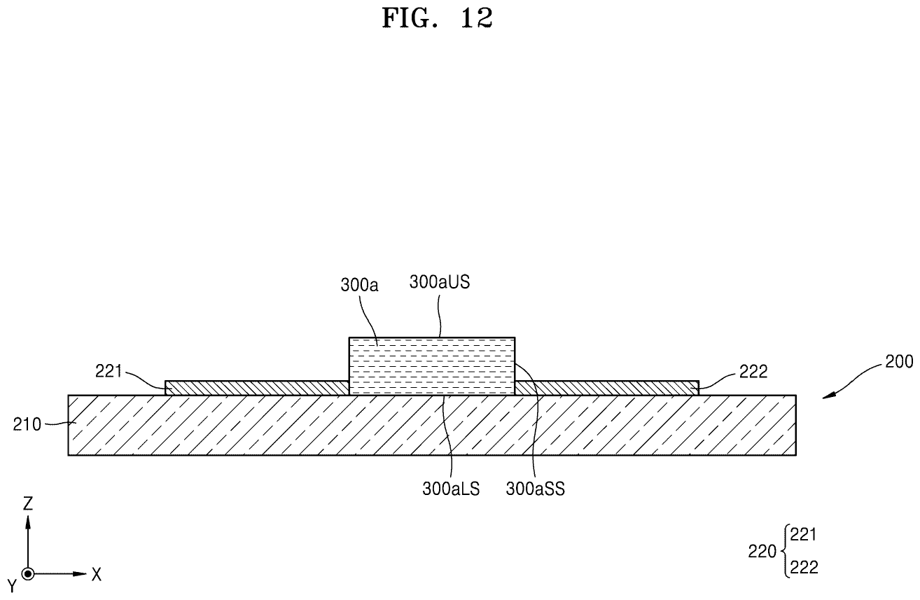

Referring to FIG. 12, an insulating layer 300 may be mounted on the PCB 200. The insulating layer 300a may have a rectangular cross-section. A method of mounting the insulating layer 300a on the PCB 200 may be the same as the method of mounting the insulating layer 300 on the PCB 200 described with reference to FIG. 9, and thus a detailed description thereof is omitted.

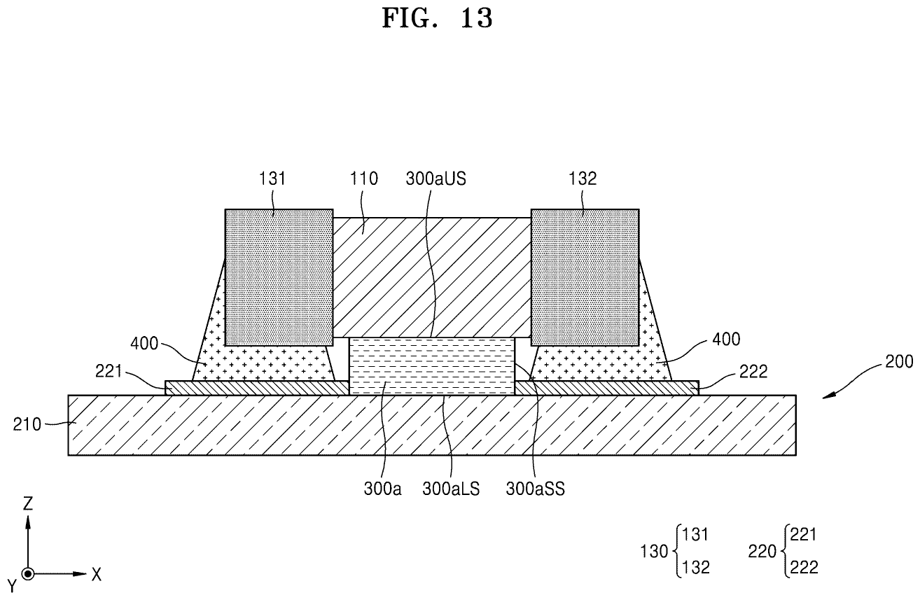

Referring to FIG. 13, the multilayer ceramic capacitor 100 may be mounted on the PCB 200 and the insulating layer 300a. After the multilayer ceramic capacitor 100 is mounted on the insulating layer 300a, the first electrode pad 221 and the first external electrode 131 may be adhered by a first adhesive member of the plurality of adhesive members 400, and the second electrode pad 222 and the second external electrode 132 may be adhered by a second adhesive member of the plurality of adhesive members 400.

Therefore, after the insulating layer 300a is mounted on the PCB 200, the multilayer ceramic capacitor 100 may be mounted on the PCB 200. The multilayer ceramic capacitor 100 may be mounted on the PCB 200 by the plurality of adhesive members 400. The plurality of adhesive members 400 may be arranged between the plurality of external electrodes 130 and the plurality of electrode pads 220 to electrically and/or physically connect the plurality of external electrodes 130 and the plurality of electrode pads 220 to each other.

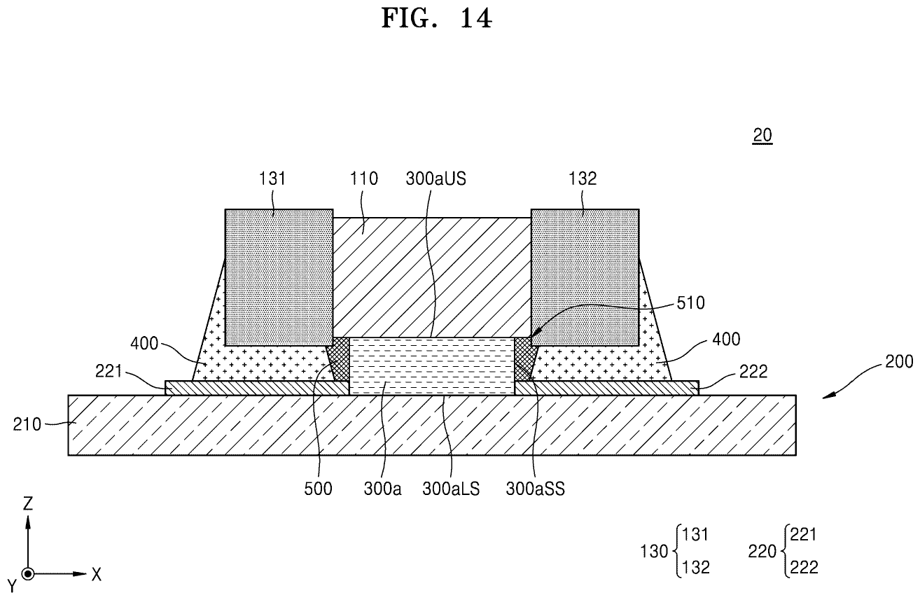

Referring to FIG. 14, an auxiliary insulating layer 500 may be formed between the insulating layer 300a and the plurality of adhesive members 400. For convenience of description, the insulating layer 300a may be referred to as a first insulating layer 300a, and the auxiliary insulating layer 500 may be referred to as a second insulating layer 500. In an embodiment, the first insulating layer 300a and the second insulating layer 500 may include materials different from each other.

The second insulating layer 500 may fill a space between the side surface 300aSS of the first insulating layer 300a and the multilayer ceramic capacitor 100. The second insulating layer 500 may fill a space between the side surface 300aSS of the first insulating layer 300a and a first adhesive member of the plurality of adhesive members 400. That is, the second insulating layer 500 may fill a space defined by the multilayer ceramic capacitor 100, the first insulating layer 300a, and a second adhesive member of the plurality of adhesive members 400.

The second insulating layer 500 may be formed by filling an insulating material into a space defined by the multilayer ceramic capacitor 100, the first insulating layer 300a, the plurality of electrode pads 220, and the plurality of adhesive members 400 and then curing the resultant. Therefore, a portion that is not filled by the first insulating layer 300a is filled by the second insulating layer 500 inside the space, and thus, voids in the space may be reduced. That is, the reliability of the electronic device 20 may increase.

While the inventive concept has been particularly shown and described with reference to embodiments thereof, it will be understood that various changes in form and details may be made therein without departing from the spirit and scope of the following claims.

1. An electronic device comprising:
a printed circuit board (PCB);
a multilayer ceramic capacitor mounted on the PCB, wherein the multilayer ceramic capacitor comprises a ceramic body and a plurality of internal electrodes inside the ceramic body; and
an insulating layer between the PCB and the multilayer ceramic capacitor, wherein
the insulating layer is in contact with the PCB and the multilayer ceramic capacitor.

2. The electronic device of claim 1, wherein a first longitudinal length of a top surface of the insulating layer is different from a second longitudinal length of a bottom surface of the insulating layer.

3. The electronic device of claim 1, wherein a first longitudinal length of a top surface of the insulating layer is identical to a second longitudinal length of a bottom surface of the insulating layer.

4. The electronic device of claim 1, wherein a Young's modulus of the insulating layer is 100 MPa or less.

5. The electronic device of claim 1, wherein a coefficient of moisture expansion of the insulating layer is 0.1% per % change in relative humidity (RH) or less.

6. The electronic device of claim 1, wherein a thickness of the insulating layer is 10—30 micrometers.

7. The electronic device of claim 1, wherein the insulating layer comprises a die attach film (DAF).

8. An electronic device comprising:
a printed circuit board (PCB), wherein the PCB comprises a base layer and a first and a second electrode pads formed on the base layer;
a multilayer ceramic capacitor mounted on the PCB; and
an insulating layer between the PCB and the multilayer ceramic capacitor, wherein the insulating layer is in contact with the PCB and the multilayer ceramic capacitor, and
wherein the multilayer ceramic capacitor comprises:
a ceramic body comprising a plurality of internal electrodes alternately arranged with a plurality of dielectric layers; and
a plurality of external electrodes on the ceramic body and electrically connected to the plurality of internal electrodes.

9. The electronic device of claim 8, wherein a top surface of the insulating layer is in contact with the multilayer ceramic capacitor.

10. The electronic device of claim 8, wherein a top surface of the insulating layer is in contact with the ceramic body and the plurality of external electrodes, respectively.

11. The electronic device of claim 8, wherein the insulating layer is spaced apart from the plurality of external electrodes in a longitudinal direction.

12. The electronic device of claim 8, wherein the insulating layer comprises:
a top surface comprising a plurality of stepped portions, a plurality of inclined portions, or combinations thereof, and
a plurality of side surfaces wherein at least one of the plurality of side surfaces comprises a plurality of stepped portions, a plurality of inclined portions, or combinations thereof.

13. The electronic device of claim 8, wherein a bottom surface of the insulating layer is in contact with the PCB.

14. The electronic device of claim 8, wherein a bottom surface of the insulating layer is in contact with the base layer, the first electrode pad and the second electrode pad.

15. The electronic device of claim 8, wherein a bottom surface of the insulating layer is located above both the first and second electrode pads along a thickness direction.

16. The electronic device of claim 8, further comprising:
a plurality of adhesive members that attaches the PCB and the multilayer ceramic capacitor to each other, wherein the insulating layer is in contact with the plurality of adhesive members.

17. An electronic device comprising:
a printed circuit board (PCB) wherein the PCB comprises a base layer and a first and a second electrode pads formed on the base layer,
a multilayer ceramic capacitor mounted on the PCB; and
an insulating layer between the PCB and the multilayer ceramic capacitor, wherein the insulating layer is in contact with the PCB and the multilayer ceramic capacitor, and
wherein the multilayer ceramic capacitor comprising:
a ceramic body comprising a plurality of first internal electrodes and a plurality of second internal electrodes alternately arranged with a plurality of dielectric layers; and
a first external electrode and a second external electrode, on opposing faces of the ceramic body, wherein the first external electrode is electrically connected to the plurality of first internal electrodes, and the second external electrode is electrically connected to the plurality of second internal electrodes.

18. The electronic device of claim 17, wherein the insulating layer is in contact with the base layer, the first electrode pad, the second electrode pad, the ceramic body, the first external electrode and the second external electrode.

19. The electronic device of claim 17, wherein a top surface of the insulating layer is adjacent to a bottom surface of the ceramic body, with respect to a thickness direction.

20. The electronic device of claim 17, wherein a bottom surface of the insulating layer is adjacent to a top surface of the base layer, with respect to a thickness direction.

21-24. (canceled)
